(19) United States
(12) Patent Application Publication
(10) Pub. No.: US 2025/0349696 A1
(43) Pub. Date: Nov. 13, 2025

(54) SEMICONDUCTOR MODULE HAVING A BUSBAR WITH SLITS, BUSBAR FOR A SEMICONDUCTOR MODULE AND METHOD FOR FABRICATING A SEMICONDUCTOR MODULE

(71) Applicant: Infineon Technologies AG, Neubiberg (DE)

(72) Inventors: Dietmar Spitzer, Volkermarkt (AT); Giampiero Ciammetti, Villach (AT); Tomas Reiter, Ottobrunn (DE); Gaetano Formato, Villach (AT)

(21) Appl. No.: 18/825,556

(22) Filed: Sep. 5, 2024

(30) Foreign Application Priority Data
May 10, 2024 (DE) 102024204358.3
Jul. 10, 2024 (DE) 102024206510.2

(51) Int. Cl. H01L 23/498; H01L 21/48; H01L 21/56; H01L 23/31

(52) U.S. Cl. CPC H01L 23/49838; H01L 21/4846; H01L 21/565; H01L 23/3121; H01L 23/49866

(57) ABSTRACT

A semiconductor module includes a power semiconductor die, an encapsulation body encapsulating the power semiconductor die, and a busbar electrically connected to the power semiconductor die and exposed from the encapsulation body. The busbar has a first side, an opposite second side, and lateral sides connecting the first and second sides. The busbar includes first and second slits arranged such that the busbar has a constriction between a distal end of the first slit and a distal end of the second slit, as viewed from above the first side. A distal end face of the slits are arranged opposite to each other and run along parallel straight lines. The distal ends of the slits are broader than the rest of the respective slit as viewed from above the first side of the busbar, the breadth being measured perpendicular to a longitudinal axis of the respective slit.

### TECHNICAL FIELD

The present disclosure relates to a semiconductor module comprising a busbar with slits, to a busbar for a semiconductor module and to a method for fabricating such a semiconductor module.

### BACKGROUND

A semiconductor module may comprise one or more busbars configured as external power contacts of the semiconductor module. The busbar(s) may be electrically connected to internal power circuitry of the semiconductor module. During operation, a current generated by the internal circuitry may flow through the busbar(s) and it may be necessary to measure the current in order to properly drive or control the internal circuitry. This may for example be done using one or more magnetic sensors arranged over the busbar(s). The busbar(s) may comprise a constriction in order to increase a current density and thereby also a magnetic field strength at the position of the magnetic sensor(s). However, tightening requirements concerning the electrical properties of semiconductor modules may make it necessary to e.g. provide a linear sensor response and/or a particularly small phase error of the sensor over a wide frequency range. Improved semiconductor modules, improved busbars for semiconductor modules as well as improved methods for fabricating a semiconductor module may help with solving these and other problems.

### SUMMARY

Various aspects pertain to a semiconductor module, comprising: at least one power semiconductor die; an encapsulation body encapsulating the power semiconductor die; a first busbar electrically connected to the power semiconductor die and exposed from the encapsulation body, the first busbar comprising a first side, an opposite second side and lateral sides connecting the first and second sides, wherein the first busbar comprises a first slit and a second slit arranged such that the first busbar has a constriction between a distal end of the first slit and a distal end of the second slit, as viewed from above the first side, wherein a distal end face of the first slit and a distal end face of the second slit are arranged opposite to each other and run along parallel straight lines, and wherein the distal ends of the first and second slits are broader than the rest of the respective slit as viewed from above the first side of the first busbar, the breadth being measured perpendicular to a longitudinal axis of the respective slit.

Various aspects pertain to a busbar configured to be connected to a semiconductor module, the busbar comprising: a first side, an opposite second side and lateral sides connecting the first and second sides; and a first slit and a second slit arranged such that the busbar has a constriction between a distal end of the first slit and a distal end of the second slit, as viewed from above the first side, wherein a distal end face of the first slit and a distal end face of the second slit are arranged opposite to each other and run along parallel straight lines, and wherein the distal ends of the first and second slits are broader than the rest of the respective slit as viewed from above the first side of the busbar, the breadth being measured perpendicular to a longitudinal axis of the respective slit.

Various aspects pertain to a method for fabricating a semiconductor module, the method comprising: providing at least one power semiconductor die; encapsulating the power semiconductor die with an encapsulation body; providing a first busbar and electrically connecting the first busbar to the power semiconductor die, the first busbar being exposed from the encapsulation body, wherein the first busbar comprises a first side, an opposite second side and lateral sides connecting the first and second sides, wherein the first busbar comprises a first slit and a second slit arranged such that the first busbar has a constriction between a distal end of the first slit and a distal end of the second slit, as viewed from above the first side, wherein a distal end face of the first slit and a distal end face of the second slit are arranged opposite to each other and run along parallel straight lines, and wherein the distal ends of the first and second slits are broader than the rest of the respective slit as viewed from above the first side of the first busbar, the breadth being measured perpendicular to a longitudinal axis of the respective slit.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 shows a sectional view of a semiconductor module comprising a busbar with first and second slits.

FIGS. 2A and 2B show a detail view of the busbar of the semiconductor module shown in FIG. 1 according to two different examples.

FIG. 3 shows a sectional view of a further semiconductor module comprising a busbar with first and second slits and further comprising a receptacle configured to receive a magnetic sensor.

FIGS. 4A and 4B show a detail view of the busbar of the semiconductor modules shown in FIGS. 1 and 3 according to two further examples.

FIG. 5 shows a perspective view of a semiconductor module comprising a plurality of busbars with slits.

FIG. 6 is a flow chart of an exemplary method for fabricating a semiconductor module comprising a busbar with slits.

FIG. 7 shows a schematic view of an electronic system comprising a busbar of the previously described busbars as well as ferrite plates.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless of whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a semiconductor module described below may use various types of semiconductor dies or circuits incorporated in the semiconductor dies, among them AC/DC or DC/DC converter circuits, inverter circuits, power MOS transistors, power Schottky diodes, JFETs (Junction Gate Field Effect Transistors), power bipolar transistors, power integrated circuits, etc. The examples may also use semiconductor dies comprising MOS transistor structures or vertical transistor structures like, for example, IGBT (Insulated Gate Bipolar Transistor) structures or, in general, transistor structures in which at least one electrical contact pad is arranged on a first main face of the semiconductor die and at least one other electrical contact pad is arranged on a second main face of the semiconductor die, opposite to the first main face of the semiconductor die.

An efficient semiconductor module as well as an efficient method for fabricating a semiconductor module may for example reduce material consumption, ohmic losses, chemical waste, etc. and may thus enable energy and/or resource savings. Improved semiconductor modules and improved methods for fabricating a semiconductor module, as specified in this description, may thus at least indirectly contribute to green technology solutions, i.e. climate-friendly solutions providing a mitigation of energy and/or resource use.

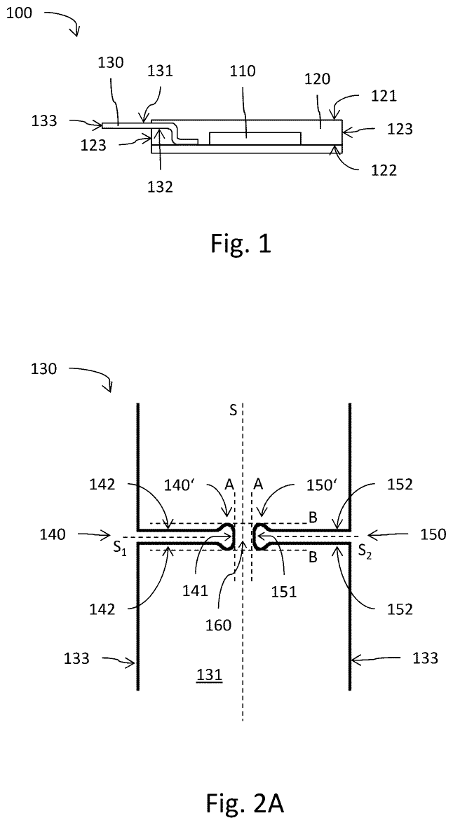

FIG. 1 shows a sectional view of a semiconductor module 100 comprising a semiconductor die 110, an encapsulation body 120 and a first busbar 130.

The semiconductor module 100 may for example be a power semiconductor module, configured to operate with a high electrical voltage and/or a strong electrical current. For example, the semiconductor module 100 may be configured to operate with a voltage of 100V or more, or 250V or more, or 500V or more, or 600V or more, or 1.2 kV or more, or 2 kV or more. Furthermore, the semiconductor module 100 may for example be rated to conduct currents of 1 A or more, or 10 A or more, or 50 A or more, or 100 A or more, or 500 A or more.

The semiconductor module 100 may comprise any suitable electrical circuit, for example a converter circuit, an inverter circuit, a half bridge circuit, a full bridge circuit, etc. The semiconductor module 100 may for example be configured for use in automotive applications. According to an example, the semiconductor module 100 is (part of) a main inverter of an electric engine. The semiconductor module 100 may be configured to be connected to a control board or driver board comprising control or driver circuitry configured to control or drive the (power) circuitry of the semiconductor module 100.

According to an example, the semiconductor module 100 comprises a single power semiconductor die 100. According to another example, the semiconductor module 100 comprises a plurality of power semiconductor dies 110. The plurality of power semiconductor dies 110 may for example be arranged on a common substrate and may be electrically connected to each other via the substrate. Some or all of the plurality of power semiconductor dies 110 may be electrically connected to the first busbar 130, e.g. via the substrate. The power semiconductor dies 110 may all be the same type of die or the power semiconductor dies 110 may be different types of dies. The semiconductor module 100 may comprise any suitable number of power semiconductor dies 110, e.g. one die, two dies, four dies, six dies, etc.

The encapsulation body 120 encapsulates the power semiconductor die 110. The encapsulation body 120 may be configured to protect the power semiconductor die 110 from environmental hazards. In the case that the semiconductor module 100 comprises a plurality of power semiconductor dies 110, all of the power semiconductor dies 110 may be encapsulated by the same encapsulation body 120. According to an example, the encapsulation body 120 comprises or consists of a plastic frame encircling an interior volume, wherein the one or more power semiconductor dies 110 are arranged within the interior volume. The interior volume may be at least partially filled with, for example, a potting material. According to another example, the encapsulation body 120 comprises or consists of a molded body. The molded body may be fabricated using any suitable molding process, for example compression molding, injection molding or transfer molding. The molded body may for example comprise inorganic filler particles configured to reduce the thermal resistance of the molded body.

The encapsulation body 120 may comprise a first side 121, an opposite second side 122 and lateral sides 123 connecting the first and second sides 121, 122. According to an example, the first busbar 130 is exposed from one of the lateral sides 123 of the encapsulation body 120. According to another example, the first busbar 130 is exposed from the first side 121 of the encapsulation body 120.

The semiconductor module 100 may comprise external contacts, e.g. control contacts, which may for example be exposed from the first side 121 of the encapsulation body 120. The external contacts may for example comprise pins, in particular press-fit pins. An application board comprising e.g. control circuitry may be arranged over the first side 121 of the encapsulation body 120 and may be electrically connected to the semiconductor module 100 via the external contacts.

According to an example, the second side 122 of the encapsulation body 120 is arranged over a substrate. The substrate may for example comprise or consist of a power electronic substrate. The substrate may e.g. be one of the type direct bonded copper (DBC), direct bonded aluminum (DAB), active metal brazed (AMB), insulated metal substrate (IMS), leadframe and printed circuit board (PCB).

The one or more power semiconductor dies 110 may be mechanically and electrically coupled to the substrate via e.g. solder joints, sintered joints, joints comprising conductive glue, etc. The first busbar 110 may be electrically and mechanically coupled to the substrate in the same way or via a welded joint.

According to an example, a baseplate and/or a heatsink may be arranged below the second side 122 of the encapsulation body 120. The baseplate and/or the heatsink may for example be configured to provide heat dissipation for the semiconductor module 100.

The first busbar 130 comprises a first side 131, an opposite second side 132 and lateral sides 133 connecting the first and second sides 131, 132. The first busbar 130 is electrically connected to the power semiconductor die 110. For example, the first busbar 130 may be connected to the power semiconductor die 110 via a substrate. The first busbar 130 may for example be soldered or sintered or welded or glued using conductive glue to the substrate. According to another example, the first busbar 130 is coupled (e.g. soldered) directly to an electrode of the power semiconductor die 110.

The first busbar 130 is exposed from the encapsulation body 120. This may mean that an external portion of the first busbar 130 protrudes from the encapsulation body 120 and an interior portion of the first busbar 130 is arranged within the encapsulation body 120. The external portion may be configured to be coupled to an external appliance, e.g. via welding and/or via mechanical means like a screw.

The first busbar 130 may comprise or consist of any suitable metal or metal alloy. For example, the first busbar 130 may comprise or consist of Al or Cu. Fabricating the first busbar 130 may for example comprise a punching process. According to an example, the first busbar is a sheet metal part.

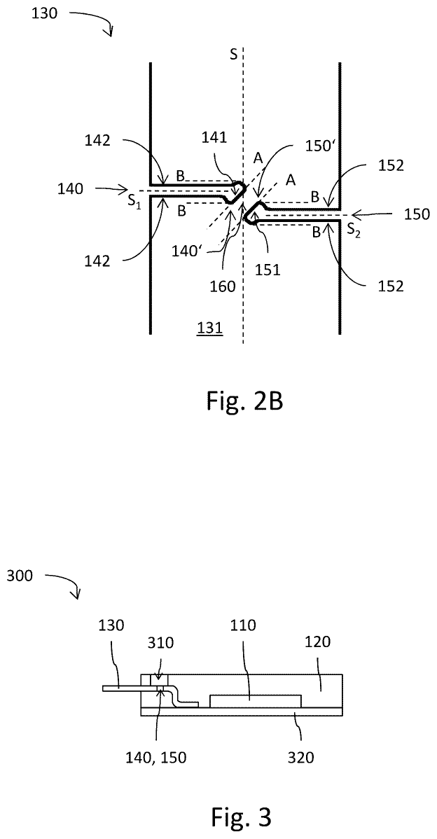

FIGS. 2A and 2B show a detail of the first busbar 130 according to different examples. In FIGS. 2A and 2B the detail of the first busbar 130 is shown from above the first side 131.

The first busbar 130 comprises a first slit 140 and a second slit 150 which are arranged such that the first busbar 130 has a constriction 160 between a distal end 140′ of the first slit 140 and a distal end 150′ of the second slit 150. The distal ends 140′, 150′ of the first and second slits 140, 150 comprise distal end faces 141, 151 which are arranged such that the distal end face 141 of the first slit 140 is opposite to the distal end face 151 of the second slit 150. Furthermore, the distal end faces 141, 151 of the first and second slits 140, 150 run along parallel straight lines (which are indicated by the dashed lines “A” in FIGS. 2A and 2B). The distal ends 140′, 150′ of the first and second slits 140, 150 are broader than the rest of the respective slit 140, 150 as viewed from above the first side of the first busbar 130 (this is indicated in FIGS. 2A and 2B by the dashed lines “B”). The breadth of the first and second slits 140, 150 is measured perpendicular to a respective longitudinal axis (S₁, respectively S₂) of the first and second slits 140, 150.

According to an example, the first and second slits 140, 150 have symmetrical contours, in particular mirror symmetrical contours, as viewed from above the first side 131 of the first busbar 130. The first and second slits 140, 150 may have a similar or identical size (e.g. within manufacturing tolerances) as viewed from above the first side 131 of the first busbar 130. The first and second slits 140, 150 may be arranged such that the longitudinal axes S₁ and S₂ are congruent.

According to an example, the first slit 140 further comprises two lateral side faces 142 that are opposite to each other and run parallel to each other. Furthermore, the lateral side faces 142 may extend from a first one of the lateral sides 133 of the first busbar 130 to the distal end face 141 of the first slit 140. Likewise, the second slit 150 may further comprise two lateral side faces 152 that are opposite to each other and run parallel to each other. The lateral side faces 152 of the second slit 150 may extend from a second one of the lateral sides 133 of the first busbar 130, which may be opposite to the first one of the lateral sides 133, to the distal end face 151 of the second slit 150. The lateral side faces 142, 152 of the first and second slits 140, 150 may in particular run parallel to the respective longitudinal axis S₁, S₂ of the first and second slits 140, 150.

The first busbar 130 may have any suitable dimensions. For example, the first busbar 130 may have a thickness measured between the first and second sides 131, 132 in the range of about 1 mm to about 5 mm. The lower limit of this range may also be about 1.2 mm, or about 1.5 mm, or about 1.8 mm, or about 2 mm and the upper limit may also be about 4 mm, or about 3 mm, or about 2.5 mm. The first busbar 130 may for example have a width measured between opposite lateral sides 133 in the range of about 10 mm to about 50 mm. The lower limit of this range may also be about 15 mm, or about 20 mm, or about 25 mm and the upper limit may also be about 40 mm, or about 35 mm, or about 30 mm.

A width of the constriction 160 in the first busbar 130 (i.e. a distance between the distal end faces 141, 151 of the first and second slits 140, 150) may for example be in the range of about 1 mm to about 4 mm. The lower limit of this range may also be about 1.2 mm, or about 1.5 mm, or about 2 mm, or about 2.2 mm, or about 2.5 mm and the upper limit may also be about 3.5 mm, or about 3 mm, or about 2.8 mm.

According to an example, the distal ends 141, 151 of the first and second slits 140, 150 are broader than the rest of the respective slit 140, 150 (the breadth of the distal ends 141, 151 may for example be measured at the broadest position and the breadth of the rest of the respective slit 140, 150 may be measured between the opposite lateral sides 142, 152). For example, the distal ends 141, 151 may be about 1.2 times or more, or 1.5 times or more, or 1.8 times or more, or 2 times or more broader than the rest of the respective slit 140, 150. A maximum breadth of the distal ends 141, 151 may for example be in the range of about 1.5 mm to about 5 mm. The lower limit of this range may also be about 1.8 mm, or about 2 mm, or about 2.2 mm, or about 2.5 mm and the upper limit may also be about 4.5 mm, or about 4 mm, or about 3.5 mm, or about 3 mm, or about 2.8 mm.

According to an example, a minimum breadth of the first and second slits 140, 150 is equal to or smaller than a thickness of the first busbar 130. According to another example, the minimum breadth of the first and second slits 140, 150 is no more than 1.2 times the thickness of the first busbar 130, or no more than 1.5 times the thickness, or no more than 2 times the thickness.

In the example shown in FIG. 2A, the distal end faces 141, 151 of the first and second slits 140, 150 run parallel to a longitudinal axis S of the first busbar 130. The distal end faces 141, 151 may be arranged perpendicular to the longitudinal axes S₁, S₂ of the first and second slits 140, 150 and/or perpendicular to the lateral side faces 142, 152 of the first and second slits 140, 150. The longitudinal axes S₁, S₂ and/or the lateral sides faces 142, 152 of the first and second slits 140, 150 may be perpendicular to the longitudinal axis S of the first busbar 130. Furthermore, the longitudinal axis S may be a symmetry axis of the first busbar 130.

In the example shown in FIG. 2B, the distal end faces 141, 151 of the first and second slits 140, 150 are arranged at a non-zero angle with respect to a longitudinal axis S of the first busbar 130. The non-zero angle may for example be within a range of about 30° to about 60°. The lower limit of this range may also be about 35°, or about 40°, or about 45° and the upper limit may also be about 55°, or about 50°.

Furthermore, in the example shown in FIG. 2B, the first and second slits 140, 150 may be offset with respect to each other along the longitudinal axis S of the first busbar 130 (in other words, the longitudinal axes S₁ and S₂ of the first and second slits 140, 150 are not congruent). The first and second slits 140, 150 may for example be offset with respect to each other along the axis S by about 0.5 mm or more, or about 1 mm or more, or about 1.5 mm or more, or about 1.7 mm or more.

According to an example, the contour of the distal end 140′ of the first slit 140 and/or the contour of the distal end 150′ of the second slit 150 has a radius of curvature of no more than 0.7 mm, as viewed from above the first side 131 of the first busbar 130. The radius of curvature may also be no more than 0.6 mm or no more than 0.5 mm.

According to an example, the busbar 130 is not part of the semiconductor module 100 but instead, the busbar 130 is configured to be connected to a semiconductor module. In this case, a semiconductor module may comprise a power tab configured as an external power contact of the semiconductor module, wherein the busbar 130 may be connected (e.g. screwed or welded) to the power tab. A current sensor (e.g. a differential hall sensor) may be arranged above the constriction 160 in the busbar 130 and may be used to measure a current flowing through the busbar 130 and the power tab of the semiconductor module. In other words, in this example the busbar 130 may be external to the semiconductor module.

FIG. 3 shows a sectional view of a further semiconductor module 300 which may be similar or identical to the semiconductor module 100. In FIG. 3, a possible position of the first and second slits 140, 150 in the first busbar 130 is indicated. It is, however, also possible that the first and second slits 140, 150 are arranged at a different position in the first busbar 130, for example more to the left (e.g. outside of the encapsulation 120) or more to the right in FIG. 3.

According to an example, the semiconductor module 300 (or the encapsulation 120 of the semiconductor module 300) comprises a receptacle 310 configured to receive a first differential hall sensor. The receptacle 310 may be arranged over the first side 131 of the first busbar 130, such that a first differential hall sensor placed into the receptacle 310 is arranged vertically above the constriction 160 between the first and second slits 140, 150. The first differential hall sensor may for example be provided as a sensor module comprising a differential hall sensor element, an encapsulation encapsulating the differential hall sensor element and external contacts configured to be connected to the semiconductor module 300 and/or to an external appliance, e.g. to a control or driver board.

The semiconductor module 300 may comprise a substrate 320. The semiconductor die 110 and possibly also the first busbar 130 may be arranged over an upper side of the substrate 320 and may be electrically connected to each other via the substrate 320. The first busbar 130 may for example be bent down such that an interior portion which is coupled to the substrate 320 is arranged in a lower plane and an exterior portion is arranged in an upper plane, different from the lower plane. However, it is also possible that the first busbar 130 does not comprise the bend shown in FIG. 3.

The first busbar 130 may for example be configured as an external power contact of the semiconductor module 300, for example a direct current (DC) power contact or an alternating current (AC) power contact. As noted further above, the semiconductor module 300 may e.g. comprise converter circuitry or inverter circuitry and the first busbar 130 may be an input or an output of this circuitry. In order for an external driver circuitry to properly control (drive) the power circuitry of the semiconductor module 300, it may be necessary to provide the driver circuitry with measurements of a current flowing through the first busbar 130. Such current measurements may be provided by a differential hall sensor arranged within the receptacle 310. The first busbar 130 comprises the constriction 160 in order to increase a magnetic field strength at the position of the sensor.

In order to accurately drive/control the circuitry of the semiconductor module 300, the differential hall sensor arranged within the receptacle 310 may need to fulfill strict requirements like having linearity in response and being (nearly) free of phase errors over a frequency range of e.g. 10 Hz to 2 kHz. However, these properties may be negatively impacted by the presence of slits in the busbar. The first and second slits 140, 150 are configured such that the negative impact is reduced or even eliminated. In particular, by making the distal ends 140′, 150′ broader than the rest of the slits 140, 150, a constriction 160 of sufficient length may be provided while keeping the slits 140, 150 as narrow as possible. Having the distal end faces 141, 151 run parallel to each other (instead of being e.g. rounded) and/or reducing the radius of curvature of the contour of the distal ends 140′, 150′ further provides positive effects on the measurement accuracy of a sensor placed above the constriction 160.

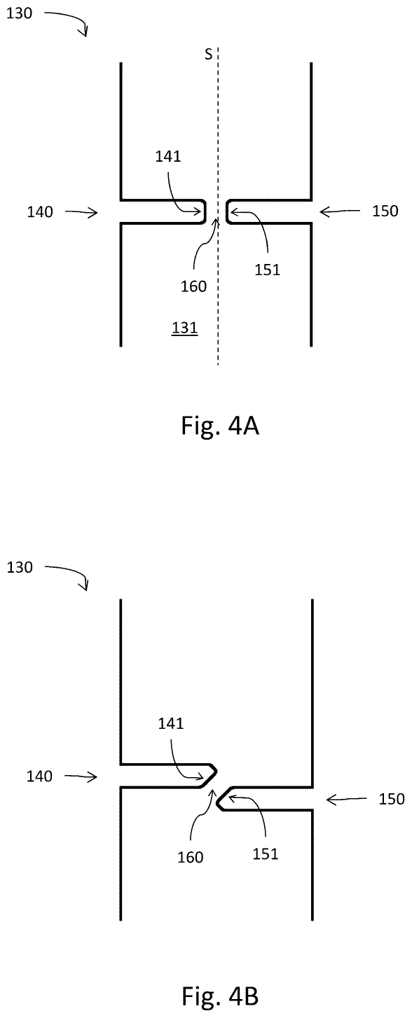

FIGS. 4A and 4B show a detail of the first busbar 130 according to further examples. In the examples shown in FIGS. 4A and 4B, the first and second slits 140, 150 do not comprise distal ends which are broader than the rest of the respective slit 140, 150. However, the distal end faces 141, 151 of the first and second slits 140, 150 still run parallel to each other. In the example shown in FIG. 4A, the distal end faces 141, 151 run parallel to the longitudinal axis S of the first busbar 130. In the example shown in FIG. 4B, the distal end faces 141, 151 are arranged at the non-zero angle with respect to the axis S, as described further above. The first and second slits 140, 150 according to the examples of FIGS. 4A and 4B may for example be as broad as disclosed further above with respect to the distal ends 140′, 150′.

The first busbar 130 according to the examples shown in FIGS. 4A and 4B may help improve sensor accuracy as described above, similar to the examples shown in FIGS. 2A and 2B. However, the first and second slits 140, 150 of the first busbar 130 according to the examples shown in FIGS. 4A and 4B overall are broader than in the examples shown in FIGS. 2A and 2B. For this reason, a heat dissipation path for dissipating heat generated by the semiconductor module 100 or 300 during operation through the first busbar 130 may have a higher thermal resistance than a heat dissipation path through the first busbar 130 according to the examples shown in FIGS. 2A and 2B.

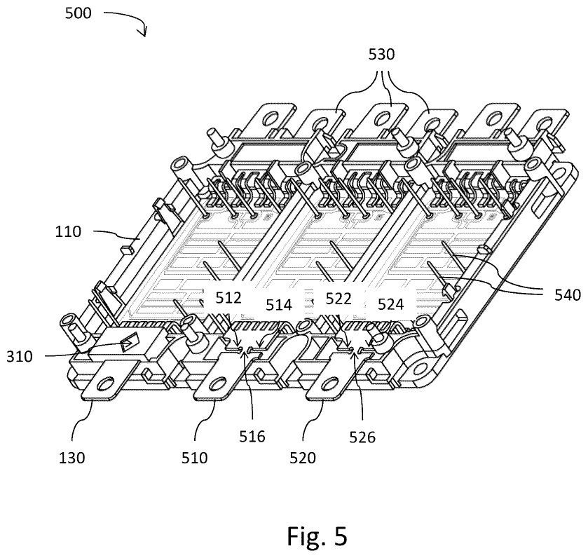

FIG. 5 shows a perspective view of a further semiconductor module 500 which may be similar or identical to the semiconductor modules 100 and 300, except for the differences described in the following.

The semiconductor module 500 comprises all components disclosed with respect to the semiconductor modules 100 and 300 and the semiconductor module 500 additionally comprises a second busbar 510 and a third busbar 520. The second busbar 510 comprises a third slit 512 and a fourth slit 514 arranged such that the second busbar 510 has a constriction 516 between a distal end of the third slit 512 and a distal end of the fourth slit 514. The third busbar 520 comprises a fifth slit 522 and a sixth slit 524 arranged such that the third busbar 520 has a constriction 526 between a distal end of the fifth slit 522 and a distal end of the sixth slit 524. The semiconductor module 500 may be configured such that a second differential hall sensor may be arranged vertically over the constriction 516 of the second busbar 510 in order to measure a current flowing through the second busbar 510 and such that a third differential hall sensor may be arranged vertically over the constriction 526 of the third busbar 520 in order to measure a current flowing through the third busbar 520. The second and third busbars 510, 520, in particular the slits of the second and third busbars 510, 520 may have the same shape, the same relative arrangement and the same dimensions as disclosed with respect to the first busbar 130.

In FIG. 5 the portion of the encapsulation body 110 above the first busbar 130 is shown in order to show the receptacle 310. The portion of the encapsulation body 110 above the second busbar 510 and the third busbar 520 is omitted in order to show the first and second slits 512, 514, 522, 524 of the second and third busbars 510, 520.

The semiconductor module 500 may comprise electrically isolating layers arranged between each of the differential hall sensors and the first, second and third busbars 130, 510 and 520 and configured to isolate the sensors from the busbars. The electrically isolating layers may for example comprise mold compound or a foil.

According to an example, the first, second and third busbars 130, 510, 520 are configured as phase current contacts of the semiconductor module 500. For example, the first, second and third busbars 130, 510 and 520 may be configured as three phase AC contacts of the semiconductor module 500. The semiconductor module 500 may comprise additional power contacts 530 which may for example be configured as DC+ and DC− contacts and may for example be arranged at a lateral side of the semiconductor module 500 which is opposite to a lateral side with the first, second and third busbars 130, 510, 520. In the example shown in FIG. 5, the additional power contacts 530 do not comprise slits like the first, second and third busbars 130, 510 and 520 do. It is however possible that one or more or all of the additional power contacts 530 also comprise the slits and constrictions described above with respect to the first busbar 130. In other words, busbars which are configured as AC contacts as well as busbars which are configured as DC contacts may comprise the slits and constrictions described herein. The semiconductor module 500 may further comprise control contacts 540 which may for example be exposed from the first side 121 of the encapsulation body 120. In the example shown in FIG. 5, the control contacts 540 comprise pins, e.g. press-fit pins.

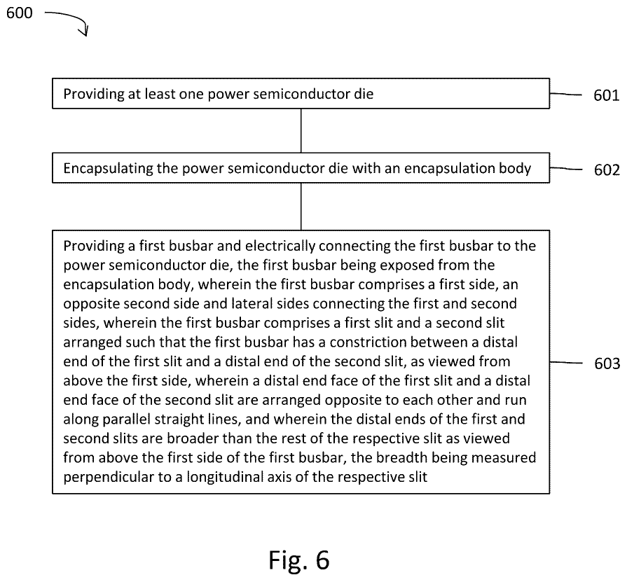

FIG. 6 is a flow chart of an exemplary method 600 for fabricating a semiconductor module. The method 600 may for example be used to fabricate the semiconductor modules 100 to 500.

The method 600 comprises at 601 a process of providing at least one power semiconductor die; at 602 the method 600 comprises a process of encapsulating the power semiconductor die with an encapsulation body; and at 603 the method 600 comprises a process of providing a first busbar and electrically connecting the first busbar to the power semiconductor die, the first busbar being exposed from the encapsulation body, wherein the first busbar comprises a first side, an opposite second side and lateral sides connecting the first and second sides, wherein the first busbar comprises a first slit and a second slit arranged such that the first busbar has a constriction between a distal end of the first slit and a distal end of the second slit, as viewed from above the first side, wherein a distal end face of the first slit and a distal end face of the second slit are arranged opposite to each other and run along parallel straight lines, and wherein the distal ends of the first and second slits are broader than the rest of the respective slit as viewed from above the first side of the first busbar, the breadth being measured perpendicular to a longitudinal axis of the respective slit.

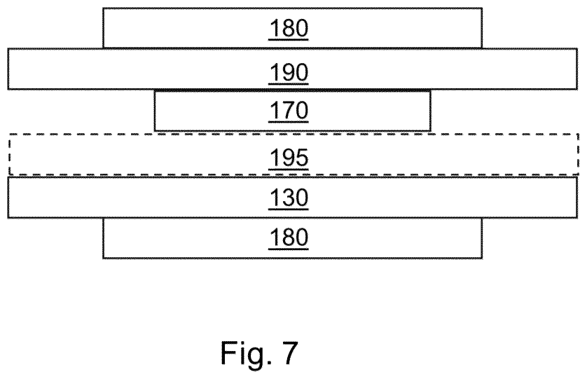

FIG. 7 shows a schematic arrangement of an electronic system comprising the busbar 130 according to any of the above mentioned busbars. A differential hall sensor 170 is arranged over the first side 131 of the first busbar 130, vertically above the constriction (not shown) wherein a ferrite plate 180 vertically aligned with the differential hall sensor 170 is arranged over a second side of the busbar 130 and/or over the differential hall sensor 170. The ferrite plate 180 above the differential hall sensor 170 may be mounted on the opposite side of a PCB 190 than the differential hall sensor 170. The ferrite plates 180 overlap with the differential hall sensor in a vertical direction, preferably covering the outer circumference of the differential hall sensor. Preferably the ferrite plate is only minimally larger than the differential hall sensor. A small size factor avoids stronger hysteresis effect inside the ferrite plates. Optionally the hall sensor may be separated from the busbar by an isolation layer 195. The ferrite plate may be placed either on one side of the differential hall sensor or on both sides. In all cases the ferrite plate boost the magnetic field and may help to enhance the signal to noise ratio.

In the following, the semiconductor module, the busbar for a semiconductor module and the method for fabricating a semiconductor module are further explained using specific examples.

Example 1 is a semiconductor module, comprising: at least one power semiconductor die; an encapsulation body encapsulating the power semiconductor die; a first busbar electrically connected to the power semiconductor die and exposed from the encapsulation body, the first busbar comprising a first side, an opposite second side and lateral sides connecting the first and second sides, wherein the first busbar comprises a first slit and a second slit arranged such that the first busbar has a constriction between a distal end of the first slit and a distal end of the second slit, as viewed from above the first side, wherein a distal end face of the first slit and a distal end face of the second slit are arranged opposite to each other and run along parallel straight lines, and wherein the distal ends of the first and second slits are broader than the rest of the respective slit as viewed from above the first side of the first busbar, the breadth being measured perpendicular to a longitudinal axis of the respective slit.

Example 2 is the semiconductor module of example 1, wherein the first slit further comprises two lateral side faces that are opposite to each other, run parallel to each other and extend from a first one of the lateral sides of the first busbar to the distal end face of the first slit, and wherein the second slit further comprises two lateral side faces that are opposite to each other, run parallel to each other and extend from a second one of the lateral sides of the first busbar, opposite to the first one of the lateral sides of the first busbar, to the distal end face of the second slit.

Example 3 is the semiconductor module of example 1 or 2, further comprising: a receptacle for a first differential hall sensor arranged over the first side of the first busbar, vertically above the constriction.

Example 4 is the semiconductor module of example 3, wherein the distal end of each slit is at least 1.5 times broader than the rest of the respective slit.

Example 5 is the semiconductor module of one of the preceding examples, wherein the distal end faces of the first and second slits run parallel to a longitudinal axis of the first busbar.

Example 6 is the semiconductor module of one of examples 1 to 4, wherein the distal end faces of the first and second slits are arranged at an angle with respect to a longitudinal axis of the first busbar, the angle being within the range of 40° to 50°.

Example 7 is the semiconductor module of one of the preceding examples, wherein a contour of the distal end of the first slit and a contour of the distal end of the second slit each has a radius of curvature of no more than 0.5 mm, as viewed from above the first side of the first busbar.

Example 8 is the semiconductor module of one of the preceding examples, wherein the first and second slits exhibit mirror symmetry.

Example 9 is the semiconductor module of one of the preceding examples, wherein a minimum breadth of the first and second slits is no more than 1.2 times a thickness of the first busbar, the breadth being measured parallel to the first side of the first busbar and the thickness being measured between the first and second sides of the first busbar.

Example 10 is the semiconductor module of one of the preceding claims, further comprising: a second busbar comprising a third slit and a fourth slit arranged such that the second busbar has a constriction between a distal end of the third slit and a distal end of the fourth slit, and a third busbar comprising a fifth slit and a sixth slit arranged such that the third busbar has a constriction between a distal end of the fifth slit and a distal end of the sixth slit.

Example 11 is a busbar configured to be connected to a semiconductor module, the busbar comprising: a first side, an opposite second side and lateral sides connecting the first and second sides; and a first slit and a second slit arranged such that the busbar has a constriction between a distal end of the first slit and a distal end of the second slit, as viewed from above the first side, wherein a distal end face of the first slit and a distal end face of the second slit are arranged opposite to each other and run along parallel straight lines, and wherein the distal ends of the first and second slits are broader than the rest of the respective slit as viewed from above the first side of the busbar, the breadth being measured perpendicular to a longitudinal axis of the respective slit.

Example 12 is the busbar of example 11, wherein the first slit further comprises two lateral side faces that are opposite to each other, run parallel to each other and extend from a first one of the lateral sides of the busbar to the distal end face of the first slit, and wherein the second slit further comprises two lateral side faces that are opposite to each other, run parallel to each other and extend from a second one of the lateral sides of the busbar, opposite to the first one of the lateral sides of the busbar, to the distal end face of the second slit.

Example 13 is the busbar of example 11 or 12, wherein the busbar is a sheet metal part.

Example 14 is the busbar of one of examples 11 to 13, wherein the distal end of each slit is at least 1.5 times broader than the rest of the respective slit.

Example 15 is an electronic system comprising the busbar of one of examples 11 to 14, a differential hall sensor arranged over the first side of the first busbar, vertically above the constriction wherein a ferrite plate vertically aligned with the differential hall sensor is arranged over a second side of the busbar and/or over the differential hall sensor.

Example 16 is a method for fabricating a semiconductor module, the method comprising: providing at least one power semiconductor die; encapsulating the power semiconductor die with an encapsulation body; providing a first busbar and electrically connecting the first busbar to the power semiconductor die, the first busbar being exposed from the encapsulation body, wherein the first busbar comprises a first side, an opposite second side and lateral sides connecting the first and second sides, wherein the first busbar comprises a first slit and a second slit arranged such that the first busbar has a constriction between a distal end of the first slit and a distal end of the second slit, as viewed from above the first side, wherein a distal end face of the first slit and a distal end face of the second slit are arranged opposite to each other and run along parallel straight lines, and wherein the distal ends of the first and second slits are broader than the rest of the respective slit as viewed from above the first side of the first busbar, the breadth being measured perpendicular to a longitudinal axis of the respective slit.

Example 17 is the method of example 16, wherein providing the first busbar comprises using a punching process in order to fabricate the first and second slits.

Example 18 is the method of example 16 or 17, further comprising: arranging an electrically isolating layer between the first differential hall sensor and the first side of the first busbar, the electrically isolating layer comprising mold compound or a foil.

Example 19 is the method of one of examples 16 to 18, wherein the distal end faces of the first and second slits run parallel to a longitudinal axis of the first busbar.

Example 20 is the method of one of examples 17 to 18, wherein the distal end faces of the first and second slits are arranged at an angle with respect to a longitudinal axis of the first busbar, the angle being within the range of 40° to 50°.

Example 21 is the method of one of claims 16 to 20, wherein a minimum breadth of the first and second slits is no more than 1.2 times a thickness of the first busbar, the breadth being measured parallel to the first side of the first busbar and the thickness being measured between the first and second sides of the first busbar.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor module, comprising:
at least one power semiconductor die;
an encapsulation body encapsulating the power semiconductor die;
a first busbar electrically connected to the power semiconductor die and exposed from the encapsulation body, the first busbar comprising a first side, an opposite second side, and lateral sides connecting the first and second sides,
wherein the first busbar comprises a first slit and a second slit arranged such that the first busbar has a constriction between a distal end of the first slit and a distal end of the second slit, as viewed from above the first side,
wherein a distal end face of the first slit and a distal end face of the second slit are arranged opposite to each other and run along parallel straight lines, and
wherein the distal ends of the first and second slits are broader than the rest of the respective slit as viewed from above the first side of the first busbar, the breadth being measured perpendicular to a longitudinal axis of the respective slit.

2. The semiconductor module of claim 1, wherein the first slit further comprises two lateral side faces that are opposite to each other, run parallel to each other, and extend from a first one of the lateral sides of the first busbar to the distal end face of the first slit, and wherein the second slit further comprises two lateral side faces that are opposite to each other, run parallel to each other, and extend from a second one of the lateral sides of the first busbar, opposite to the first one of the lateral sides of the first busbar, to the distal end face of the second slit.

3. The semiconductor module of claim 1, further comprising a receptacle for a first differential hall sensor arranged over the first side of the first busbar, vertically above the constriction.

4. The semiconductor module of claim 3, wherein the distal end of each slit is at least 1.5 times broader than the rest of the respective slit.

5. The semiconductor module of claim 1, wherein the distal end faces of the first and second slits run parallel to a longitudinal axis of the first busbar.

6. The semiconductor module of claim 1, wherein the distal end faces of the first and second slits are arranged at an angle with respect to a longitudinal axis of the first busbar, the angle being within the range of 40° to 50°.

7. The semiconductor module of claim 1, wherein a contour of the distal end of the first slit and a contour of the distal end of the second slit each has a radius of curvature of no more than 0.5 mm, as viewed from above the first side of the first busbar.

8. The semiconductor module of claim 1, wherein the first and second slits exhibit mirror symmetry.

9. The semiconductor module of claim 1, wherein a minimum breadth of the first and second slits is no more than 1.2 times a thickness of the first busbar, the breadth being measured parallel to the first side of the first busbar and the thickness being measured between the first and second sides of the first busbar.

10. The semiconductor module of claim 1, further comprising:
a second busbar comprising a third slit and a fourth slit arranged such that the second busbar has a constriction between a distal end of the third slit and a distal end of the fourth slit; and
a third busbar comprising a fifth slit and a sixth slit arranged such that the third busbar has a constriction between a distal end of the fifth slit and a distal end of the sixth slit.

11. A busbar configured to be connected to a semiconductor module, the busbar comprising:
a first side;
a second side opposite the first side;
lateral sides connecting the first and second sides; and
a first slit and a second slit arranged such that the busbar has a constriction between a distal end of the first slit and a distal end of the second slit, as viewed from above the first side,
wherein a distal end face of the first slit and a distal end face of the second slit are arranged opposite to each other and run along parallel straight lines, and
wherein the distal ends of the first and second slits are broader than the rest of the respective slit as viewed from above the first side of the busbar, the breadth being measured perpendicular to a longitudinal axis of the respective slit.

12. The busbar of claim 11, wherein the first slit further comprises two lateral side faces that are opposite to each other, run parallel to each other, and extend from a first one of the lateral sides of the busbar to the distal end face of the first slit, and wherein the second slit further comprises two lateral side faces that are opposite to each other, run parallel to each other, and extend from a second one of the lateral sides of the busbar, opposite to the first one of the lateral sides of the busbar, to the distal end face of the second slit.

13. The busbar of claim 11, wherein the busbar is a sheet metal part.

14. The busbar of claim 11, wherein the distal end of each slit is at least 1.5 times broader than the rest of the respective slit.

15. An electronic system, comprising:
the busbar of claim 11;
a differential hall sensor arranged over the first side of the first busbar, vertically above the constriction; and
a ferrite plate vertically aligned with the differential hall sensor and arranged over a second side of the busbar and/or over the differential hall sensor.

16. A method for fabricating a semiconductor module, the method comprising:
providing at least one power semiconductor die;
encapsulating the at least one power semiconductor die with an encapsulation body; and
electrically connecting a first busbar to the at least one power semiconductor die, the first busbar being exposed from the encapsulation body,
wherein the first busbar comprises a first side, an opposite second side, and lateral sides connecting the first and second sides,
wherein the first busbar comprises a first slit and a second slit arranged such that the first busbar has a constriction between a distal end of the first slit and a distal end of the second slit, as viewed from above the first side,
wherein a distal end face of the first slit and a distal end face of the second slit are arranged opposite to each other and run along parallel straight lines, and
wherein the distal ends of the first and second slits are broader than the rest of the respective slit as viewed from above the first side of the first busbar, the breadth being measured perpendicular to a longitudinal axis of the respective slit.

17. The method of claim 16, further comprising:
using a punching process to fabricate the first and second slits of the first busbar.

18. The method of claim 16, further comprising:
arranging an electrically isolating layer between the first differential hall sensor and the first side of the first busbar, the electrically isolating layer comprising mold compound or a foil.

19. The method of claim 16, wherein the distal end faces of the first and second slits run parallel to a longitudinal axis of the first busbar.

20. The method of claim 16, wherein the distal end faces of the first and second slits are arranged at an angle with respect to a longitudinal axis of the first busbar, the angle being within the range of 40° to 50°.

21. The method of claim 16, wherein a minimum breadth of the first and second slits is no more than 1.2 times a thickness of the first busbar, the breadth being measured parallel to the first side of the first busbar and the thickness being measured between the first and second sides of the first busbar.
